(19) United States
(12) Patent Application Publication
(10) Pub. No.: US 2011/0278553 A1
(43) Pub. Date: Nov. 17, 2011

(54) ORGANIC LIGHT-EMITTING APPARATUS AND METHOD OF MANUFACTURING THE SAME

(75) Inventors: Oh-June KWON, Yongin-City (KR); Seung-Yong SONG, Yongin-City (KR); Young-Seo CHOI, Yongin-City (KR); Ji-Hun RYU, Yongin-City (KR); Young-Cheol JOO, Yongin-City (KR); Jin-Hwan JEON, Yongin-City (KR); Sun-Young JUNG, Yongin-City (KR)

(73) Assignee: Samsung Mobile Display Co., Ltd., Yongin-City (KR)

(21) Appl. No.: 13/040,587

(22) Filed: Mar. 4, 2011

(30) Foreign Application Priority Data
May 17, 2010 (KR) 10-2010-0046029

(51) Int. Cl. H01L 51/54; H01L 51/56

(52) U.S. Cl. 257/40; 438/46; 257/E51.026; 257/E51.001

(57) ABSTRACT

An organic light-emitting apparatus having high rigidity and preventing deterioration of an organic light-emitting device therein by use of a crosslinking agent including a SiH group in the surface of a core particle.

### CROSS-REFERENCE TO RELATED APPLICATIONS

This application claims the benefit of Korean Patent Application No. 10-2010-0046029, filed on May 17, 2010, in the Korean Intellectual Property Office, the disclosure of which is incorporated herein in its entirety by reference.

### BACKGROUND

1. Field

The present embodiments relate to an organic light-emitting apparatus and a method of manufacturing the same, and more particularly, to an organic light-emitting apparatus having high rigidity and low dark spot formation and a method of manufacturing the same.

2. Description of the Related Art

Organic light-emitting apparatuses are one type of flat display apparatuses in which an organic emission layer is interposed between two opposing electrodes, electrons injected from an electrode of the two opposing electrodes and holes injected from the other electrode are combined in the organic emission layer, and light-emitting molecules in the organic emission layer are excited through the combination of electrons and holes and then returned to a base state so that energy from the light-emitting molecules is released as light.

Organic light-emitting apparatuses have excellent visibility, small weight, and reduced thickness, and require a low driving voltage. Thus, they have drawn attention as the next-generation of display apparatuses.

In an organic light-emitting apparatus, a display unit is formed on a first substrate and a second substrate is disposed on the display unit, and the first substrate and the second substrate are bonded to each other with a sealing unit. The display unit also includes an organic light-emitting device that may deteriorate by internal and external factors. An emission layer of the organic light-emitting device may deteriorate by internal factors such as oxygen generated from an ITO electrode and a reaction occurring at an interface between the emission layer and neighboring layers. The organic light-emitting device may also deteriorate by external factors such as external moisture, oxygen, UV rays, and conditions for manufacturing the organic light-emitting device. In particular, external oxygen and moisture cause seriously affect the lifetime of an organic light-emitting device. Thus, the organic light-emitting device has to be sufficiently packed.

External impurities such as oxygen and moisture may permeate into the organic light-emitting apparatus through the sealing unit that bonds the first substrate to the second substrate (encapsulation substrate), particularly, through an interface between the sealing unit and the second substrate and damage the display unit.

In order to prevent damage from the permeation of impurities and impact, a method of disposing a filling film or filling agent between the first substrate and the second substrate, and disposing a dam between the filling film or filling agent and the sealing unit has been developed. The filling agent interposed between the first substrate and the second substrate may be polyorganosiloxane having a vinyl group at one end cured by a crosslinking agent. The crosslinking agent may have a siloxane structure with a relatively short molecular length and a plurality of SiH groups, and excess crosslinking agent is used so that all of polyorganosiloxane having a vinyl group at one end is involved in the reaction. Crosslinking agent remainders that are not involved in the reaction and have high reactivity may cause side reactions with the display unit and deform a material used to form an emission region. Thus, the display unit may have a defect of a partial non-emission region.

### SUMMARY

The present embodiments provide an organic light-emitting apparatus having high rigidity and preventing deterioration of an organic light-emitting device.

The present embodiments also provide a method of manufacturing the organic light-emitting apparatus.

According to an aspect of the present embodiments, there is provided an organic light-emitting apparatus including: a first substrate; a second substrate disposed opposite to the first substrate; a display unit disposed between the first substrate and the second substrate and including an organic light-emitting device; a sealing unit that is disposed between the first substrate and the second substrate to surround the display unit and to bond the first substrate to the second substrate; and a filling agent that is disposed in the inner side of the sealing unit to cover the display unit and includes a cured product of a core particle, a crosslinking agent introduced to the surface of the core particle and having at least one SiH group, and polyorganosiloxane having at least one alkenyl group at one end.

The core particle may be selected from the group consisting of fumed silica, fumed titanium dioxide, calcium carbonate, calcium silicate, titanium dioxide, ferric oxide, carbon black, and zinc oxide.

A diameter of the core particle may be from about 10 to 500 nm.

The crosslinking agent may include a compound represented by Formula 1 below:

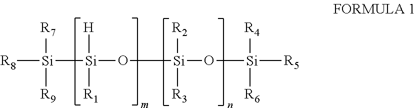

where R₁ to R₉ are each independently a hydrogen atom, a deuterium atom, or a substituted or unsubstituted C₁-C₂₀ alkyl group, m is an integer from 1 to 50, and n is an integer from 0 to 50.

The crosslinking agent may include a compound represented by Formula 2 below:

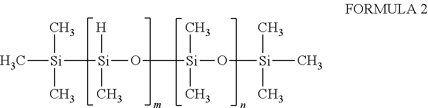

where m is an integer from 1 to 50, and n is an integer from 0 to 50.

The polyorganosiloxane may include a compound represented by Formula 3 below:

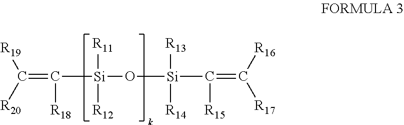

where R₁₁ to R₁₄ are each independently a substituted or unsubstituted C₁-C₂₀ alkyl group, R₁₅ to R₂₀ are each independently a hydrogen atom or a deuterium atom, and k is an integer from 200 to 1600.

The polyorganosiloxane may include a compound represented by Formula 4 below:

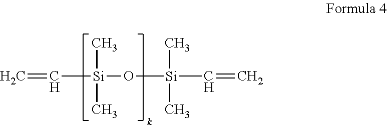

where k is an integer from 200 to 1600.

The filling agent may fill a space between the first substrate and the second substrate.

The organic light-emitting device may include: a first electrode; a second electrode disposed opposite to the first electrode; and an organic layer interposed between the first electrode and the second electrode.

The filling agent may directly contact a surface of the second electrode.

The organic light-emitting apparatus may further including a protective layer that is disposed between the filling agent and the second electrode.

According to another aspect of the present embodiments, there is provided a method of manufacturing an organic light-emitting apparatus, the method including: preparing a first substrate and a second substrate such that a sealing unit is formed to surround a display unit including an organic light-emitting device; filling a core particle, a crosslinking agent introduced to the surface of the core particle and having at least one SiH group, and polyorganosiloxane having at least one alkenyl group at one end, in the inner side of the sealing unit; aligning the first substrate and the second substrate to be opposite to each other and bonding the first substrate to the second substrate; curing the sealing unit; and curing the crosslinking agent and the polyorganosiloxane.

The crosslinking agent having at least one SiH group may be introduced to the surface of the core particle by coating.

Curing the crosslinking agent and the polyorganosiloxane may be performed at a temperature from about 50 to 200° C. for 10 minutes to 10 hours.

### BRIEF DESCRIPTION OF THE DRAWINGS

The above and other features and advantages of the present embodiments will become more apparent by describing in detail example embodiments thereof with reference to the attached drawings in which:

FIG. 1 is a schematic sectional view showing a structure of an organic light-emitting apparatus according to an embodiment;

FIG. 2 is a schematic partial plan view of the organic light-emitting apparatus of FIG. 1;

FIG. 3 is a detailed sectional view of the organic light-emitting apparatus of FIG. 1;

FIG. 4 is a schematic diagram for describing a dark spot forming process in a display unit by a crosslinking agent in a general organic light-emitting apparatus;

FIG. 5A is an emission photograph of an organic light-emitting apparatus according to Example 1; and

FIG. 5B is an emission photograph of an organic light-emitting apparatus according to Comparative Example 1.

### DETAILED DESCRIPTION OF THE PREFERRED EMBODIMENT

Hereinafter, the present embodiments will be described in detail by explaining example embodiments with reference to the attached drawings. However, this is not intended to limit the present embodiments to particular modes of practice.

In the drawings, like reference numerals denote like elements, and the sizes and thicknesses of layers and regions are exaggerated for clarity. It will be understood that when a portion such as a layer, membrane, region, and plate, is referred to as being “on” another portion, it can be directly on the other portion, or intervening portions may also be present therebetween. On the contrary, it will also be understood that when a portion is referred to as being “directly on” another portion, it can be directly on the other portion.

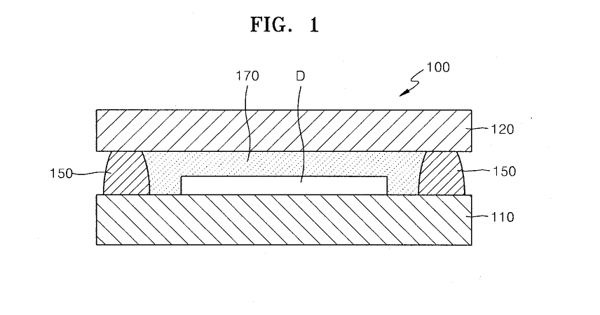

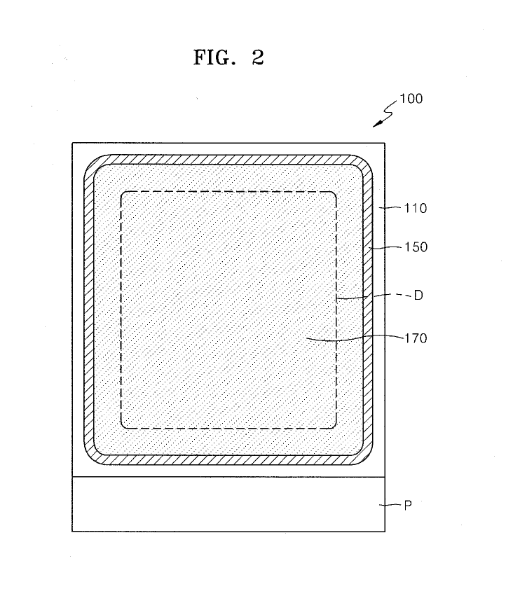

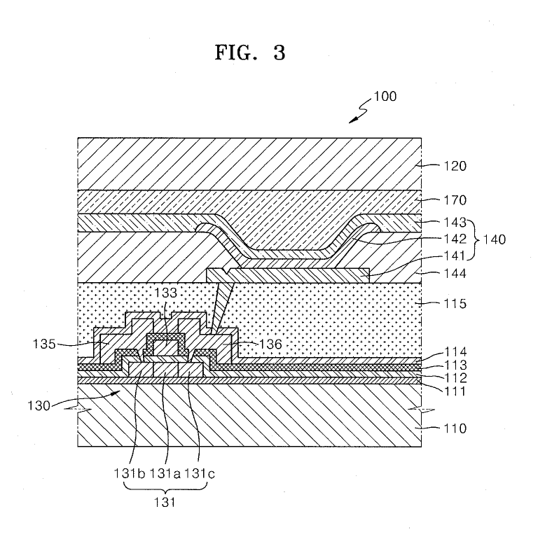

FIG. 1 is a schematic sectional view showing a structure of an organic light-emitting apparatus according to an embodiment. FIG. 2 is a schematic partial plan view of the organic light-emitting apparatus of FIG. 1. FIG. 3 is a detailed sectional view of the organic light-emitting apparatus of FIG. 1.

Referring to FIGS. 1 to 3, an organic light-emitting apparatus 100 according to an embodiment includes: a first substrate 110; a second substrate 120 disposed opposite to the first substrate 110; a display unit D disposed between the first substrate 110 and the second substrate 120 and including an organic light-emitting device 140; a sealing unit 150 that is disposed between the first substrate 110 and the second substrate 120 to surround the display unit D and bonds the first substrate 110 to the second substrate 120; and a filling agent 170 that is disposed in the inner side of the sealing unit 150 to cover the display unit D and includes a cured product of core particles, a crosslinking agent introduced to the surface of the core particles and having at least one SiH group, and polyorganosiloxane having at least one alkenyl group at one end.

The first substrate 110 is disposed opposite to the second substrate 120. The display unit D and a pad portion P are disposed on a surface of the first substrate 110 facing the second substrate 120, and the sealing unit 150 is disposed to surround the display unit D. The filling agent 170 fills a space formed when the sealing unit 150 bonds the first substrate 110 to the second substrate 120 so as to cover the display unit D.

The first substrate 110 may be a transparent glass substrate in which silicon dioxide (SiO₂) is used as a main component. However, the present embodiments are not limited thereto, and the first substrate 110 may be substrates comprising various materials such as plastics. The plastic material for forming the first substrate 110 may be an insulating organic material. For example, the insulating organic material may be selected from the group consisting of polyethersulphone (PES), polyacrylate (PAR), polyetherimide (PEI), polyethyelenen naphthalate (PEN), polyethyeleneterephthalate (PET), polyphenylene sulfide (PPS), polyallylate, polyimide, polycarbonate (PC), cellulose tri acetate (TAC), and cellulose acetate propionate (CAP).

If the organic light emitting apparatus is a bottom emission type in which images are displayed in a direction toward the first substrate 110, the first substrate 110 may comprise a transparent material. However, if the organic light emitting apparatus is a top emission type in which images are displayed in a direction opposite to the first substrate 110, the first substrate 110 may comprise a non-transparent material. In this case, the first substrate 110 may comprise metal. The metal for forming the first substrate 110 may include at least one selected from the group consisting of carbon, iron, chromium, manganese, nickel, titanium, molybdenum, stainless steel (SUS), an Invar alloy, an Inconel alloy, and a Kovar alloy, but is not limited thereto. For example, the first substrate 110 may comprise a metal foil.

A buffer layer 111 may further be formed on the first substrate 110 to improve planarization of the first substrate 110 and prevent penetration of impurities.

The display unit D may include a plurality of organic light-emitting devices 140 and a plurality of thin film transistors (TFTs) 130 electrically connected to the organic light-emitting devices 140. An organic light-emitting apparatus may be classified as a passive matrix (PM) type or an active matrix (AM) type according to control of the organic light-emitting devices 140 by using the TFTs 130. The organic light-emitting apparatus 100 according to the present embodiment may be applied to both the AM and PM type organic light-emitting apparatuses. Hereinafter, an AM type organic light-emitting apparatus 100 will be described in detail.

An active layer 131 of the TFTs 130 is formed of a semiconductor material on the buffer layer 111. A gate insulating layer 112 is formed to cover the active layer 131. The active layer 131 may comprise an inorganic semiconductor material, such as amorphous silicon or polysilicon, or an organic semiconductor material. The active layer 131 includes a source region 131b, a drain region 131c, and a channel region 131a between the source and drain regions 131b and 131c.

A gate electrode 133 is disposed on the gate insulating layer 112. An interlayer insulating layer 113 is disposed to cover the gate electrode 133. A source electrode 135 and a drain electrode 136 are disposed on the interlayer insulating layer 113. A passivation layer 114 and a planarization layer 115 are sequentially disposed to cover the source and drain electrodes 135 and 136.

The gate insulating layer 112, the interlayer insulating layer 113, the passivation layer 114, and the planarization layer 115 may be formed as an insulator and may have a single-layered structure or a multi-layered structure including an inorganic material, an organic material, or an organic/inorganic composite material. The stack structure of the TFTs 130 described above is just an example and a variety of TFT structures may be used.

The pad portion P is disposed at a side of the display unit D. The pad portion P includes a plurality of pad electrodes (not shown) that are connected to various conductive lines (not shown) of the display unit D for driving display devices, such as data lines, scan lines, and power supply lines, and transmit a signal input from an external device to each of the organic light-emitting devices 140 of the display unit D via the conductive lines.

A first electrode 141, which functions as an anode of the organic light-emitting devices 140, is disposed on the planarization layer 115, and a pixel defining layer 144 formed of an insulating material is disposed to cover the first electrode 141. After a predetermined opening is formed in the pixel defining layer 144, an organic layer 142 of the organic light-emitting device 140 is formed in a region defined by the opening. A second electrode 143, which functions as a cathode of the organic light-emitting device 140, is disposed on the pixel defining layer 144 to cover all pixels. The polarities of the first electrode 141 and the second electrode 143 may be reversed.

The organic layer 142 between the first electrode 141 and the second electrode 143 may include at least one layer selected from the group consisting of a hole injection layer (HIL), a hole transport layer (HTL), an emission layer (EML), a hole blocking layer (HBL), an electron transport layer (ETL), and an electron injection layer (EIL).

For example, the organic-light emitting device 140 may have a single stack structure or a multi-stack structure, each stack including the first electrode 141/HIL (not shown)/HTL (not shown)/EML (not shown)/ETL (not shown)/EIL (not shown)/the second electrode 143 or including the first electrode 141/HIL/HTL/EML/HBL (not shown)/ETL/EIL/the second electrode 143.

The first electrode 141 may comprise an anode forming material having a high work function by using deposition or sputtering. The first electrode 141 may be a transparent electrode or a reflective electrode. If the first electrode 141 is a transparent electrode, the first electrode 141 may comprise ITO, IZO, SnO₂, ZnO, or In₂O₃. If the first electrode 141 is a reflective electrode, the first electrode 141 may include a reflective layer formed of silver (Ag), magnesium (Mg), aluminum (Al), platinum (Pt), palladium (Pd), gold (Au), nickel (Ni), neodymium (Nd), iridium (Ir), chromium (Cr), or a compound thereof, and a transparent layer formed of ITO, IZO, ZnO, or In₂O₃.

A HIL formed of a HIL-forming material by using thermal vacuum deposition or spin coating is disposed on the first electrode 141. Examples of the HIL-forming material include a phthalocyanine compound, such as CuPc and copperphthalocyanine; a star-burst type amine derivative, such as TCTA, m-MTDATA, and m-MTDAPB; soluble and conductive polymer such as polyaniline/dodecylbenzenesulfonic acid (Pani/DBSA); poly(3,4-ethylenedioxythiophene)/poly(4-styrenesulfonate (PEDOT/PSS): polyaniline/camphor sulfonic acid (Pani/CSA); and (polyaniline)/poly(4-styrenesulfonate) (PANI/PSS), but are not limited thereto.

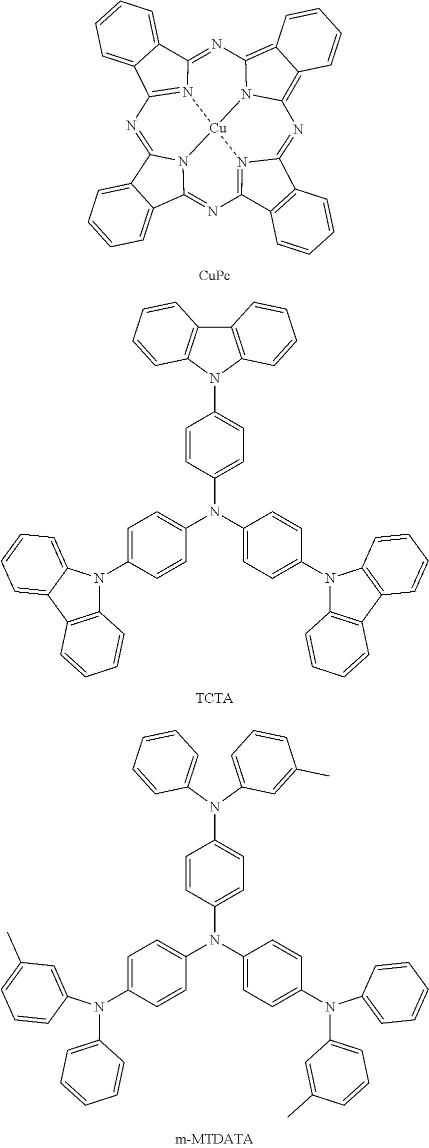

A HTL formed of a HTL-forming material by using thermal vacuum deposition or spin coating is disposed on the HIL. Examples of the HTL-forming material include 1,3,5-tricarbazolylbenzene, 4,4′-biscarbazolylbiphenyl, polyvinyl carbazole, m-biscarbazolylphenyl, 4,4′-biscarbazolyl-2,2′-dimethylbiphenyl, 4,4′,4″-tri(N-carbazolyl)triphenylamine, 1,3,5-tri(2-carbazolylphenyl)benzene, 1,3,5-tris(2-carbazolyl-5-methoxyphenyl)benzene, bis(4-carbazolylphenyl)benzene, 1,3,5-tris(2-carbazolyl-5-methoxyphenyl)benzene, bis(4-carbazolyl)silane, N,N′-bis(3-methylphenyl)-N,N′-diphenyl-[1,1-biphenyl]-4,4′-diamine (TPD), N,N′-diphenyl-N,N′-bis(1-naphthyl)-(1,1′-biphenyl)-4,4′-diamine (NPB), poly(9,9-dioctylfluorene-co-N-(4-butylphenyl)diphenylamine (TFB), and poly(9,9-dioctylfluorene-co-bis-(4-butylphenyl-bis-N,N-phenyl-1,4-phenylenediamine (PFB), but are not limited thereto.

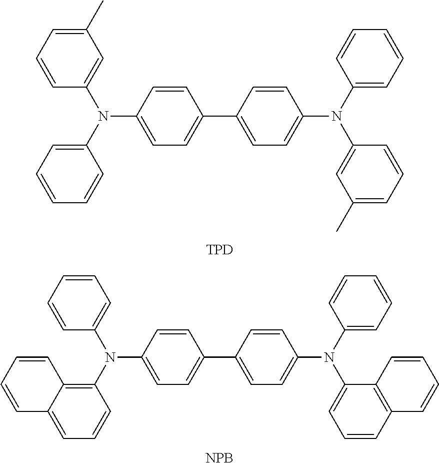

An EML is formed on the HTL. Examples of an EML-forming material include a host such as 4,4′-biscarbazolylbiphenyl (CBP), TCB, TCTA, SDI-BH-18, SDI-BH-19, SDI-BH-22, SDI-BH-23, dmCBP, Liq, TPBI, Balq, or BCP; a fluorescent dopant such as IDE102 or IDE105, which are available from Idemitsu Co.; a green phosphorescent dopant, such as Ir(ppy)₃; and a blue phosphorescent dopant, such as (4,6-F₂ ppy)₂, but are not limited thereto. The EML may be formed using thermal vacuum deposition.

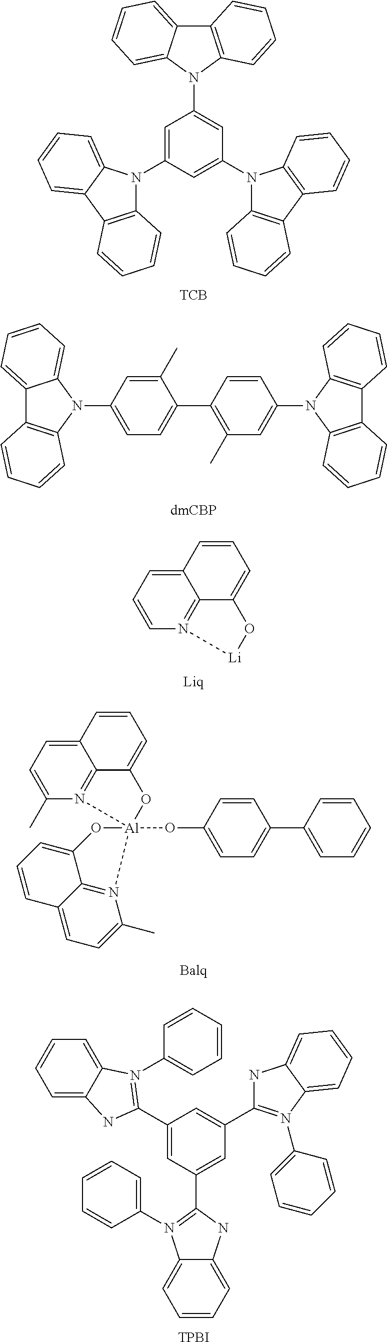

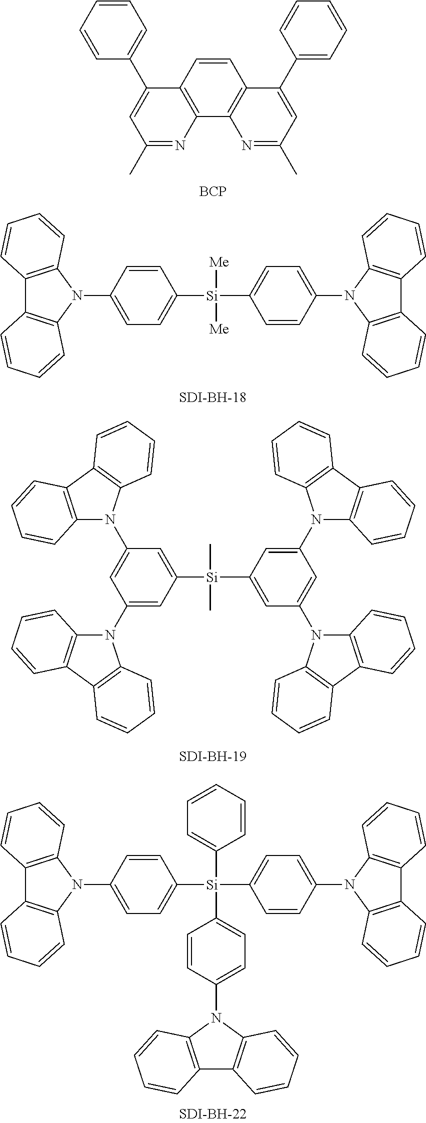

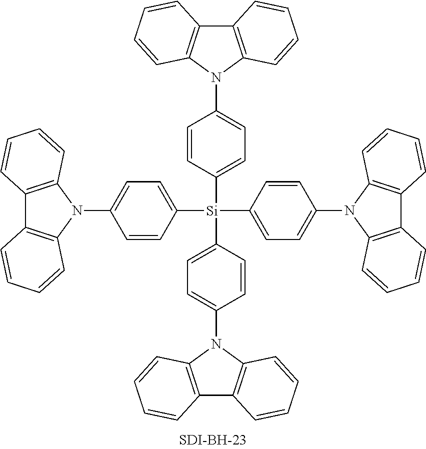

The doping concentration may be from about 0.5 to 12 wt %, but is not limited thereto.

If a phosphorescent dopant is used in the EML, an HBL formed of a HBL-forming material by using thermal vacuum deposition may further be disposed on the EML in order to prevent diffusion of triplet excitons or holes into the ETL. The HBL-forming material may be any material having electron transporting capabilities and a higher ionization potential than a light-emitting compound, for example, Balq or BCP, but is not limited thereto.

An ETL may be formed on the HBL by using vacuum deposition or spin coating. An ETL-forming material may be Alq3 that is known in the art.

An EIL may be stacked on the ETL. Examples of an EIL-forming material include LiF, NaCl, CsF, Li₂O, and BaO, but are not limited thereto.

A second electrode 143 formed of a cathode-forming metal by using thermal vacuum deposition is disposed on the EIL. The second electrode 143 may be a transparent electrode or a reflective electrode. If the second electrode 143 is a transparent electrode, the second electrode 143 may include a layer formed of a material selected from the group consisting of lithium (Li), calcium (Ca), lithium fluoride/calcium (LiF/Ca), lithium fluoride/aluminum (LiF/Al), aluminum (Al), silver (Ag), magnesium (Mg), and a combination thereof on the organic layer 142, and an auxiliary electrode or a bus electrode line formed of a transparent conductive material selected from the group consisting of ITO, IZO, ZnO, and In₂O₃ on the layer. If the second electrode 143 is a refractive electrode, the second electrode 143 may comprise a material selected from the group consisting of Li, Ca, Al, Mg, LiF/Ca, LiF/Al, Al/Li, Mg/In, Mg/Ag, and a combination thereof.

Although not shown, a spacer for maintaining a gap between the organic light-emitting device 140 and the second substrate 120 may further be formed above the pixel defining layer 144.

The sealing unit 150 is disposed on a surface of the first substrate 110 facing the second substrate 120 to surround a circumferential surface of the display unit D.

The sealing unit 150 may also be disposed on a surface of the second substrate 120 facing the first substrate 110. The sealing unit 150 bonds the first substrate 110 to the second substrate 120 to prevent external oxygen and moisture from penetrating into the organic light-emitting device 140.

The sealing unit 150 may be an organic material such as epoxy or an inorganic material such as frit that does not require an additional moisture absorbent. If frit is used, a glass material in a paste form is applied to the first substrate 110 and the second substrate 120 and the glass material are melted by using a laser beam or infrared ray. While the melted glass material is cured, the first substrate 110 and the second substrate 120 are sealed.

If frit, an inorganic material, is used as the sealing unit 150 and disposed on the first substrate 110, the fit may be directly formed on an inorganic insulating layer that extends directly from the display unit D in order to reinforce interface contact between the frit and the first substrate 110. The inorganic insulating layer that extends directly from the display unit D indicates that an inorganic insulating layer such as the gate insulating layer 112, the interlayer insulating layer 113, and the passivation layer 114 is formed on the circumferential surface of the display unit D on which the sealing unit 150 is disposed, during the manufacturing of the above-mentioned TFT 130.

However, when an external shock is applied to the organic light-emitting apparatus 100, frit easily breaks. Thus, stress may concentrate on an adhering surface of the first substrate 110 or the second substrate 120 on which the sealing unit 150 is applied, and thus, cracks may occur in the adhering surface and may spread into the entire surface. In order to prevent this problem, a filling agent is applied to an inner space of the organic light-emitting apparatus 100 that is formed when the first substrate 110 and the second substrate 120 are bonded to each other. The filling agent 170 prevents the organic light-emitting apparatus 100 from damaging by an external shock since the filling agent 170 including a material having predetermined elasticity and viscosity fills the inner space of the organic light-emitting apparatus 100.

The filling agent 170 includes a cured product of a core particle, a crosslinking agent introduced to the surface of the core particle and having at least one SiH group, and polyorganosiloxane having at least one alkenyl group at one end. When the organic light-emitting apparatus 100 is filled with the crosslinking agent having at least one SiH group and polyorganosiloxane having a vinyl group and heated, curing reaction between the crosslinking agent and the polyorganosiloxane occur to increase rigidity of the organic light-emitting apparatus 100. However, the crosslinking agent with a SiH group has high mobility since the SiH group is attached to a relatively short molecular chain. Thus, some of the crosslinking agent is not involved in a reaction with polyorganosiloxane having a vinyl group and may contact the organic light-emitting device 140 of the display unit D. Since the silane moiety of the crosslinking agent having a SiH group has high reactivity, the crosslinking agent may be involved in a reaction with an organic material constituting the organic light-emitting device 140 when the crosslinking agent contacts the organic light-emitting device 140. For example, the crosslinking agent having a SiH group permeates into the organic light-emitting device 140 through a fine dent formed in the organic light-emitting device 140 and cause side reactions with a material that is used to form an emission region. Thus, a part of the emission region is deformed into a non-emission region.

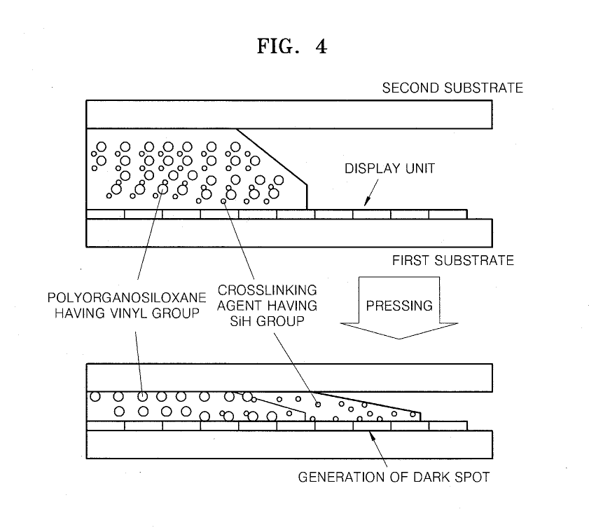

FIG. 4 is a schematic diagram for describing a process of forming a dark spot by a reaction between the crosslinking agent having a SiH group and the organic light-emitting device 140 the mobility difference between the polyorganosiloxane having a vinyl group and the crosslinking agent having a SiH group when polyorganosiloxane having a vinyl group and the crosslinking agent having a SiH group are used as the filling agent 170.

Referring to FIG. 4, if polyorganosiloxane having a vinyl group and the crosslinking agent having a SiH group are applied to the display unit D, the second substrate 120 is covered, and a pressure is applied thereto, the crosslinking agent having a SiH group with a high mobility migrates toward the display unit D according to the mobility difference between the polyorganosiloxane having a vinyl group and the crosslinking agent having a SiH group. The crosslinking agent having a SiH group that arrives at the display unit D permeates into the display unit D through a fine dent and the SiH group having high reactivity is involved in a reaction with an organic material of the organic light-emitting device 140, thereby forming a dark spot.

According to an embodiment, the crosslinking agent having a SiH group may be introduced to the surface of a core particle in order to reduce the mobility of the crosslinking agent. A core particle, a crosslinking agent introduced to the surface of the core particle and having at least one SiH group, and polyorganosiloxane having at least one alkenyl group at one end are filled in an inner space formed when the first substrate 110 and the second substrate 120 are bonded to each other, and a high-temperature UV ray or laser beam is irradiated into the space to cause a curing reaction between the crosslinking agent and the polyorganosiloxane, and thereby forming a filling agent 170.

Since the crosslinking agent having a SiH group is introduced to the surface of the core particle, the mobility of the crosslinking agent is reduced, so that the reaction between the SiH group and the organic material of the organic light-emitting device 140 may be inhibited. The crosslinking agent having a SiH group may be introduced to the surface of the core particle by coating, or the like without limitation.

The core particle may be selected from the group consisting of fumed silica, fumed titanium dioxide, calcium carbonate, calcium silicate, titanium dioxide, ferric oxide, carbon black, and zinc oxide. In this regard, the fumed silica and fumed titanium dioxide may be used as an enhancing inorganic additive, and calcium carbonate, calcium silicate, titanium dioxide, ferric oxide, carbon black, and zinc oxide may be used as a non-enhancing organic additive.

A diameter of the core particle may be from about 10 to 500 nm. In order to manufacture a thin organic light-emitting apparatus, the distance between the first substrate 110 on which the display unit D is formed and the second substrate 120 that is used as an encapsulation layer is reduced. For example, the distance between the first substrate 110 and the second substrate 120 may be from about 2 to 4 μm. Accordingly, the size of the core particle that constitutes the filling agent 170 that is filled between the first substrate 110 and the second substrate 120 should be sufficiently small in order to prevent damage to the display unit D. If the diameter of the core particle is within the above range, damage to the display unit D may be prevented.

The amount of the core particle may be from about 300 to 10000 parts by weight based on 100 parts by weight of the crosslinking agent introduced to the surface of the core particle and having at least one SiH group. If the amount of the core particle is within the above range, the crosslinking agent may be efficiently introduced to the surface of the core particle.

The crosslinking agent having at least one SiH group may be a compound represented by Formula 1 below.

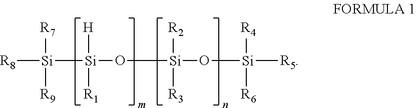

In Formula 1, R₁ to R₉ are each independently a hydrogen atom, a deuterium atom, or a substituted or unsubstituted C₁-C₂₀ alkyl group, m is an integer from 1 to 50, and n is an integer from 0 to 50. For example, R₁ to R₉ may be each independently selected from the group consisting of methyl, ethyl, n-propyl, iso-propyl, n-butyl, sec-butyl, and t-butyl.

The crosslinking agent may be a compound represented by Formula 2 below.

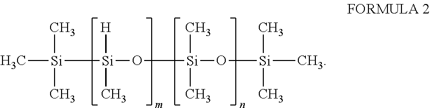

In Formula 2, m is an integer from 1 to 50, and n is an integer from 0 to 50.

Polyorganosiloxane having at least one alkenyl group at one end may be a compound represented by Formula 3 below.

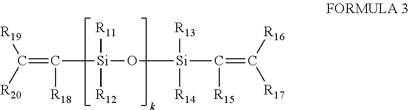

In Formula 3, R₁₁ to R₁₄ are each independently a substituted or unsubstituted C₁-C₂₀ alkyl group, R₁₅ to R₂₀ are each independently a hydrogen atom or a deuterium atom, and k is an integer from 200 to 1600. For example, R₁₁ to R₁₄ may be each independently selected from the group consisting of methyl, ethyl, n-propyl, iso-propyl, n-butyl, sec-butyl, and t-butyl, and R₁₅ to R₂₀ may be each independently a hydrogen atom.

Polyorganosiloxane may be a compound represented by Formula 4 below.

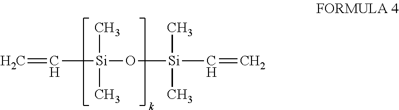

In Formula 4, k is an integer from 200 to 5.

Rigidity of the organic light-emitting apparatus 100 is increased since the space between the first substrate 110 and the second substrate 120 is filled with the filling agent 170 that includes a cured product of a core particle, a crosslinking agent introduced to the surface of the core particle and having at least one SiH group, and polyorganosiloxane having at least one alkenyl group at one end. Rigidity of the organic light-emitting apparatus 100 may be efficiently increased by making the filling agent 170 in a direct contact with the entire surface of the second electrode 143 of the organic light-emitting device 140. If a conductive additive is added to the filling agent 170, a protective layer may further be disposed between the second electrode 143 and the filling agent 170.

A second substrate 120 is formed opposite to the first substrate 110 on which the display unit D is formed. The second substrate 120 is disposed on the display unit D and bonded to the first substrate 110 by the sealing unit 150. The second substrate 120 may be a glass substrate, a plastic substrate formed of, for example, acryl, or a metal substrate.

A method of manufacturing an organic light-emitting apparatus 100 according to another embodiment will be described.

A first substrate 110 on which a sealing unit 150 is formed to surround a display unit D including an organic light-emitting device 140 is prepared. A second substrate 120 that is used as an encapsulation unit is prepared. The sealing unit 150 may also be formed on the second substrate 120. The sealing unit 150 may be fit, and the fit may be formed on an insulating layer directly extending from the display unit D.

The core particle, the crosslinking agent introduced to the surface of the core particle and having at least one SiH group, and polyorganosiloxane having at least one alkenyl group at one end are applied to the inner side of the sealing unit 150. For example, the core particle, the crosslinking agent, and the polyorganosiloxane may be dropped in the center of the display unit D of the inner side of the sealing unit 150. The crosslinking agent may be formed having at least one SiH group on the surface of the core particle by coating.

The first substrate 110 and the second substrate 120 are aligned to be opposite to each other and bonded to each other, and the sealing unit 150 is cured by irradiating a laser beam or UV ray to the sealing unit 150.

Finally, the crosslinking agent and polyorganosiloxane that are filled in the inner side of the sealing unit 150 are cured by irradiating laser beams or UV rays thereto. The curing process may be performed in various manners according to the amount of the crosslinking agent and polyorganosiloxane and additives, for example, at a temperature from about 50 to 200□ for 10 minutes to 10 hours.

Hereinafter, one or more embodiments will be described in detail with reference to the following examples. These examples are not intended to limit the purpose and scope of the one or more embodiments.

### EXAMPLE

### Example 1

A display unit including an organic light-emitting device was formed on a SiO₂ glass substrate (first substrate). A 15 Ω/cm² (1,2000□) ITO glass substrate (available from Corning Co.) was cut to a size of 50 mm×50 mm×0.7 mm, ultrasonically washed with isopropyl alcohol for 5 minutes and then with pure water for 5 minutes, and washed again with UV ozone for 30 minutes to manufacture an anode (first electrode). Then, m-MTDATA was vacuum deposited on the first electrode to form a HIL with a thickness of 750 Å. Then, NPB was vacuum deposited on the HIL to a thickness of 150 Å to form a HTL. After forming the HTL, DSA as a host and 3% TBPe as a dopant were deposited on the HTL to form an EML having a thickness of 300 Å. Alq3 was vacuum deposited on the EML to form an ETL having a thickness of 200 Å. LiF was vacuum deposited on the ETL to form an EIL having a thickness of 80 Å, and Al was vacuum deposited on the EIL to form LiF/Al electrode having a thickness of 3000 Å.

Then, the display unit was surrounded by fit, and 50 parts by weight of fumed silica having a diameter of 100 nm coated with 1.2 parts by weight of a crosslinking agent represented by Formula 1 and 48.8 parts by weight of polyorganosiloxane represented by Formula 2 were applied onto the LiF/Al electrode. Then, an encapsulation substrate (second substrate) is placed thereon, and frit was cured using a laser beam. Then, the crosslinking agent and polyorganosiloxane were cured at 85° C. for 1 hour by heating.

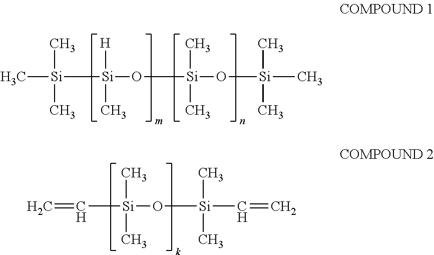

Here, m=25, n=0, and k=800.

### Comparative Example 1

The experiment was conducted in the same manner as in Example 1, except that 1.2 parts by weight of a crosslinking agent represented by Formula 1 was coated on the LiF/Al electrode and 48.8 parts by weight of polyorganosiloxane represented by Formula 2 was applied thereto (No fumed silica).

### Evaluation of Rigidity of Organic Light-Emitting Apparatus

Rigidity of the organic light-emitting apparatuses manufactured according to Example 1 and Comparative Example 1 measured in a 3-axis rigidity test is shown in Table 1 below.

TABLE 1

| | No. of | Average Rigidity |
|---|---|---|
| | Experiment | (N/nm) |
| Example 1 | 20 | 60.2 |
| Comparative Example 1 | 20 | 45.6 |

Referring to Table 1, the rigidity of the organic light-emitting apparatus manufactured according to Example 1 was greater than that of the organic light-emitting apparatus manufactured according to Comparative Example 1 by more than about 30%.

### Evaluation of Emission Characteristics of Organic Light-Emitting Device

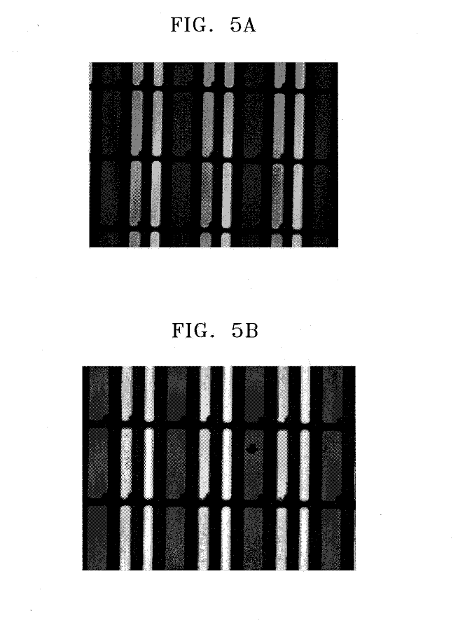

Formation of dark spots was detected from the organic light-emitting apparatuses manufactured according to Example 1 and Comparative Example 1 and compared. FIGS. 5A and 5B are emission photographs of organic light-emitting apparatuses manufactured according to Example 1 and Comparative Example 1.

Referring to FIGS. 5A and 5B, the organic light-emitting apparatus according to Comparative Example 1 has dark spots, but the organic light-emitting apparatus according to Example 1 has no dark spots.

As described above, the organic light-emitting apparatus according to the present embodiments can have high rigidity and deterioration of the organic light-emitting device can be prevented by using the crosslinking agent having a SiH group that is introduced to the surface of the core particle.

While the present embodiments have been particularly shown and described with reference to example embodiments thereof, it will be understood by those of ordinary skill in the art that various changes in form and details may be made therein without departing from the spirit and scope of the present embodiments as defined by the following claims.

What is claimed is:

1. An organic light-emitting apparatus comprising:
a first substrate;
a second substrate disposed opposite to the first substrate;
a display unit disposed between the first substrate and the second substrate and comprising an organic light-emitting device;
a sealing unit that is disposed between the first substrate and the second substrate to surround the display unit and to bond the first substrate to the second substrate; and
a filling agent that is disposed in the inner side of the sealing unit to cover the display unit;
wherein the filling agent comprises a cured product of a core particle, a crosslinking agent on the surface of the core particle and having at least one SiH group, and polyorganosiloxane having at least one alkenyl group on at least one end.

2. The organic light-emitting apparatus of claim 1, wherein the core particle is selected from the group consisting of fumed silica, fumed titanium dioxide, calcium carbonate, calcium silicate, titanium dioxide, ferric oxide, carbon black, and zinc oxide.

3. The organic light-emitting apparatus of claim 1, wherein a diameter of the core particle is from about 10 to 500 nm.

4. The organic light-emitting apparatus of claim 1, wherein the crosslinking agent comprises a compound represented by Formula 1 below: 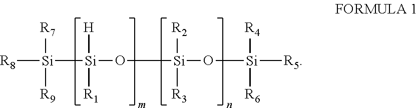
where R₁ to R₉ are each independently a hydrogen atom, a deuterium atom, or a substituted or unsubstituted C₁-C₂₀ alkyl group, m is an integer from 1 to 50, and n is an integer from 0 to 50.

5. The organic light-emitting apparatus of claim 4, wherein R₁ to R₉ are each independently selected from the group consisting of methyl, ethyl, n-propyl, iso-propyl, n-butyl, sec-butyl, and t-butyl.

6. The organic light-emitting apparatus of claim 1, wherein the crosslinking agent comprises a compound represented by Formula 2 below: 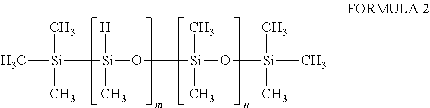
where m is an integer from 1 to 50, and n is an integer from 0 to 50.

7. The organic light-emitting apparatus of claim 1, wherein the polyorganosiloxane comprises a compound represented by Formula 3 below: 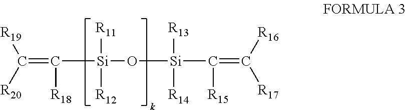
where R₁₁ to R₁₄ are each independently a substituted or unsubstituted C₁-C₂₀ alkyl group, R₁₅ to R₂₀ are each independently a hydrogen atom or a deuterium atom, and k is an integer from 200 to 1600.

8. The organic light-emitting apparatus of claim 7, wherein R₁₁ to R₁₄ are each independently selected from the group consisting of methyl, ethyl, n-propyl, iso-propyl, n-butyl, sec-butyl, and t-butyl, and R₁₅ to R₂₀ are each independently a hydrogen atom.

9. The organic light-emitting apparatus of claim 1, wherein the polyorganosiloxane comprises a compound represented by Formula 4 below: 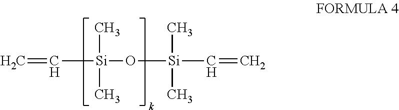
where k is an integer from 200 to 1600.

10. The organic light-emitting apparatus of claim 1, wherein the filling agent fills a space between the first substrate and the second substrate.

11. The organic light-emitting apparatus of claim 1, wherein the organic light-emitting device comprises: a first electrode; a second electrode disposed opposite to the first electrode; and an organic layer interposed between the first electrode and the second electrode.

12. The organic light-emitting apparatus of claim 11, wherein the filling agent directly contacts a surface of the second electrode.

13. The organic light-emitting apparatus of claim 11, further comprising a protective layer that is disposed between the filling agent and the second electrode.

14. A method of manufacturing an organic light-emitting apparatus, the method comprising:
preparing a first substrate and a second substrate such that a sealing unit is formed to surround a display unit comprising an organic light-emitting device;
filling a core particle, a crosslinking agent introduced to the surface of the core particle and having at least one SiH group, and polyorganosiloxane having at least one alkenyl group at one end, in the inner side of the sealing unit;
aligning the first substrate and the second substrate to be opposite to each other and bonding the first substrate to the second substrate;
curing the sealing unit; and
curing the crosslinking agent and the polyorganosiloxane.

15. The method of claim 14, wherein the crosslinking agent having at least one SiH group is introduced to the surface of the core particle by coating.

16. The method of claim 14, wherein curing the crosslinking agent and the polyorganosiloxane is performed at a temperature of from about 50 to 200° C. for from about 10 minutes to about 10 hours.

17. The method of claim 14, wherein the core particle is selected from the group consisting of fumed silica, fumed titanium dioxide, calcium carbonate, calcium silicate, titanium dioxide, ferric oxide, carbon black, and zinc oxide.

18. The method of claim 14, wherein the crosslinking agent comprises a compound represented by Formula 1 below: 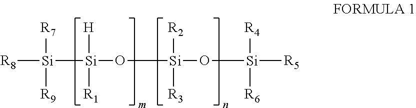
where R₁ to R₉ are each independently a hydrogen atom, a deuterium atom, or a substituted or unsubstituted C₁-C₂₀ alkyl group, m is an integer from 1 to 50, and n is an integer from 0 to 50.

19. The method of claim 14, wherein the polyorganosiloxane comprises a compound represented by Formula 3 below: 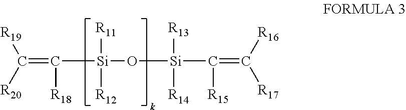
where R₁₁ to R₁₄ are each independently a substituted or unsubstituted C₁-C₂₀ alkyl group, R₁₅ to R₂₀ are each independently a hydrogen atom or a deuterium atom, and k is an integer from 200 to 1,600.

20. The method of claim 14, wherein the crosslinking agent comprises a compound represented by Formula 2 below: 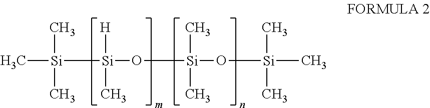
where m is an integer from 1 to 50, and n is an integer from 0 to 50.
